(19) United States
(12) Patent Application Publication
(10) Pub. No.: US 2026/0304692 A1
(43) Pub. Date: Oct. 1, 2026

(54) CONTROL DEVICE, COOLING SYSTEM, MOVING OBJECT, CONTROL METHOD, AND STORAGE MEDIUM

(71) Applicant: HONDA MOTOR CO., LTD., Tokyo (JP)

(72) Inventor: Naoki Kamimura, Wako-shi (JP)

(21) Appl. No.: 19/629,209

(22) Filed: Mar. 26, 2026

(30) Foreign Application Priority Data
Mar. 28, 2025 (JP) 2025-055306

(51) Int. Cl. H05K 7/20; H02K 9/19

(52) U.S. Cl. CPC H05K 7/20281; H02K 9/19

(57) ABSTRACT

A control device includes a determination unit that determines whether coolant is to be supplied to a cooling flow path from a first port located at one end of the cooling flow path or from a second port located at the other end of the cooling flow path, and a control unit that performs first supply control for supplying coolant from the first port to the cooling flow path when the determination unit determines that coolant is to be supplied from the first port to the cooling flow path, and performs second supply control for supplying coolant from the second port to the cooling flow path when the determination unit determines that coolant is to be supplied from the second port to the cooling flow path.

### CROSS-REFERENCE TO RELATED APPLICATIONS

This application is based upon and claims the benefit of priority from Japanese Patent Application No. 2025-055306 filed on Mar. 28, 2025, the contents of which are incorporated herein by reference.

### BACKGROUND OF THE INVENTION

### Field of the Invention

The present disclosure relates to a control device, a cooling system, a moving object, a control method, and a storage medium.

### Description of the Related Art

WO 2025/018370 A1 discloses a technique for cooling a coil provided in a rotary electrical machine with a coolant.

### SUMMARY OF THE INVENTION

There is a need to appropriately cool a rotating electric machine.

The present disclosure has the object of satisfying the aforementioned need.

A first aspect of the present disclosure is a control device provided in a cooling system configured to supply coolant to a cooling flow path provided in a rotating electric machine, the control device including: a determination unit configured to determine whether coolant is to be supplied to the cooling flow path from a first port located at one end of the cooling flow path or from a second port located at another end of the cooling flow path; and a control unit configured to perform first supply control for supplying coolant from the first port to the cooling flow path when the determination unit determines that coolant is to be supplied from the first port to the cooling flow path, and perform second supply control for supplying coolant from the second port to the cooling flow path when the determination unit determines that coolant is to be supplied from the second port to the cooling flow path.

A second aspect of the present disclosure is a cooling system including a control device according to the first aspect, wherein a flow path for cooling an inverter with coolant is disposed between a discharge port of a pump configured to discharge coolant and the cooling flow path of the rotating electric machine, the inverter being configured to supply alternating-current power to the rotating electric machine.

A third aspect of the present disclosure is a moving object including a cooling system including the control device according to the first aspect.

A fourth aspect of the present disclosure is a control method for a cooling system configured to supply coolant to a cooling flow path provided in a rotating electric machine, the control method including: a determination step of determining whether coolant is to be supplied to the cooling flow path from a first port located at one end of the cooling flow path or from a second port located at another end of the cooling flow path; and a control step of performing first supply control for supplying coolant from the first port to the cooling flow path when the determination step determines that coolant is to be supplied from the first port to the cooling flow path, and performing second supply control for supplying coolant from the second port to the cooling flow path when the determination step determines that coolant is to be supplied from the second port to the cooling flow path.

A fifth aspect of the present disclosure is a program for causing a computer to execute the control method according to the fourth aspect.

According to the present disclosure, the rotating electric machine can be cooled in a suitable manner.

The above and other objects, features, and advantages of the present invention will become more apparent from the following description when taken in conjunction with the accompanying drawings, in which a preferred embodiment of the present invention is shown by way of illustrative example.

### BRIEF DESCRIPTION OF THE DRAWINGS

FIG. 1 is a schematic view of a moving object;

FIG. 2 is a schematic view of a cooling system according to a first embodiment;

FIG. 3 is a schematic view of the cooling system according to the first embodiment;

FIG. 4 is a flowchart of a cooling process according to the first embodiment;

FIG. 5 is a graph showing a relationship between time and the internal temperature of a rotating electric machine;

FIG. 6 is a schematic view of a cooling system according to a second embodiment;

FIG. 7 is a schematic view of the cooling system according to the second embodiment;

FIG. 8 is a flowchart of a cooling process according to the second embodiment;

FIG. 9 is a graph showing a relationship between time and the internal temperature of a rotating electric machine; and

FIG. 10 is a schematic view of a cooling system according to a third embodiment.

### DETAILED DESCRIPTION OF THE INVENTION

In recent years, electrification of moving objects has been promoted. The electric moving object is equipped with a rotating electric machine such as a motor, a generator, or the like. The coils and the like provided in the rotating electric machine are cooled by a coolant (cooling fluid) flowing through a cooling flow path. The coolant is supplied from a supply port to the inside of the rotating electric machine, absorbs heat from the coil and the like, and is discharged from a discharge port to the outside of the rotating electric machine.

Inside the rotating electric machine, the temperature of the coolant flowing on the downstream side (discharge port side) of the cooling flow path is higher than the temperature of the coolant flowing on the upstream side (supply port side) of the cooling flow path. Therefore, a difference in cooling capacity of the coolant occurs between the upstream side and the downstream side of the cooling flow path. As a result, a difference in cooling temperature occurs inside the rotating electric machine. As a means for reducing the difference in cooling temperature inside the rotating electric machine, it is conceivable to increase the flow rate of the coolant. However, in order to increase the flow rate of the coolant, a large pump and a large radiator are required. In this case, the weight of the entire cooling system may increase. This leads to a reduction in the cruising distance (cruising range) of the moving object, a deterioration in fuel efficiency (electric power consumption efficiency), and the like.

The present disclosure makes it possible to reduce a difference in cooling temperature inside a rotating electric machine while suppressing an increase in the size of the system.

### 1. Moving Object 100

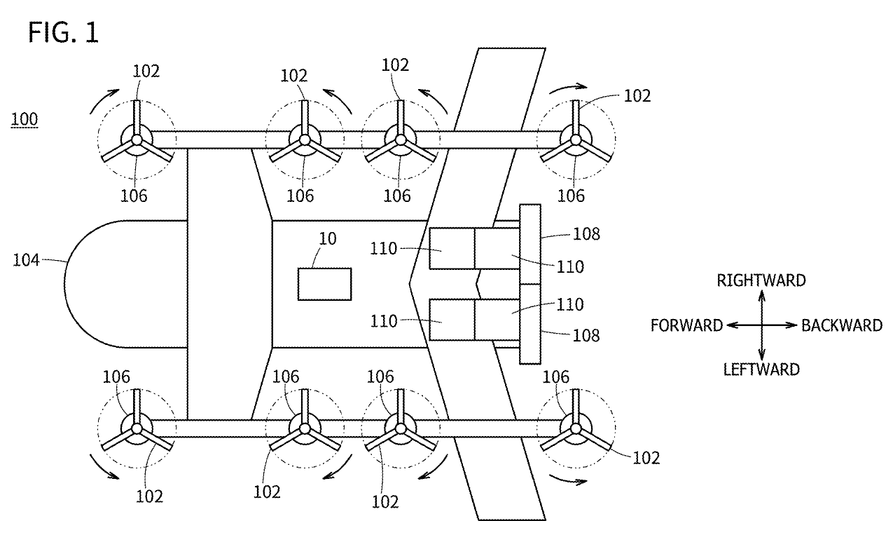

FIG. 1 is a schematic view of a moving object 100. The moving object 100 according to an embodiment is an electric vertical take-off and landing aircraft (eVTOL aircraft). The moving object 100 includes eight VTOL rotors 102. The VTOL rotor 102 generates thrust in the upward direction with respect to the airframe 104. The moving object 100 includes eight electric motors 106. One electric motor 106 drives one VTOL rotor 102. The moving object 100 includes four cruise rotors 108. The cruise rotor 108 generates thrust in the forward direction with respect to the airframe 104. The moving object 100 includes two electric motors 110. Two electric motors 110 drive one cruise rotor 108. The moving object 100 includes a cooling system 10. The moving object 100 is not limited to an aircraft, and may be a ship, an automobile, a train, or the like.

### 2. Cooling System 10 according to First Embodiment

### 2-1. Configuration of Cooling System 10

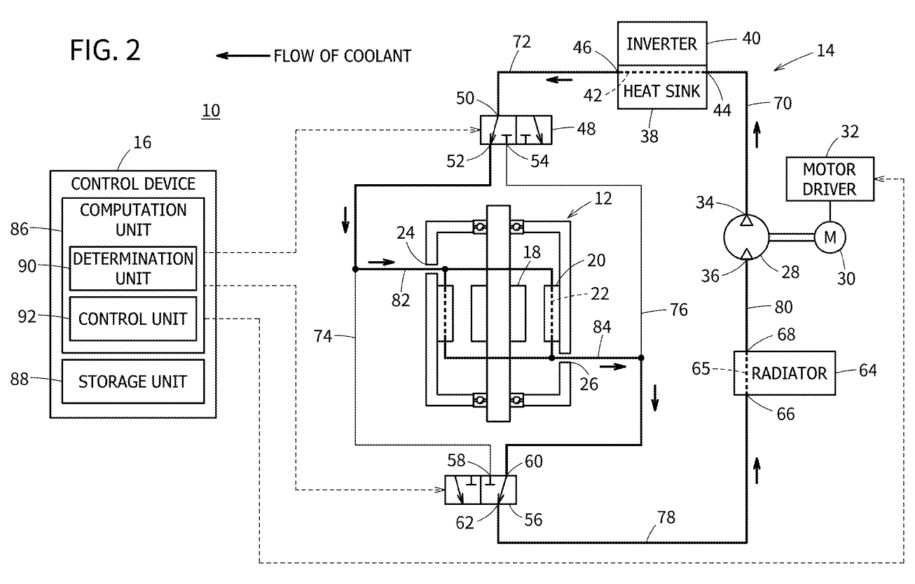

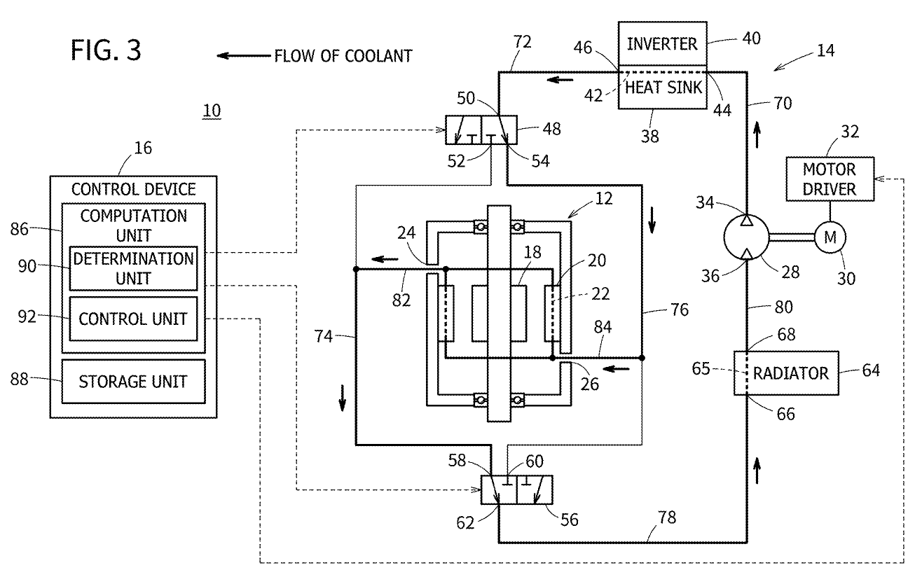

FIGS. 2 and 3 are schematic views of the cooling system 10 according to the first embodiment. FIG. 2 shows the cooling system 10 in a state where first supply control is being performed. FIG. 3 shows the cooling system 10 in a state where second supply control is being performed. The configuration of the cooling system 10 will be described with reference to FIG. 2, and will be described with reference to FIG. 3 as appropriate. The cooling system 10 includes a cooling circuit 14 and a control device 16. The cooling circuit 14 cools a rotating electric machine 12. The control device 16 controls the flow of the coolant in the cooling circuit 14.

### Rotating Electric Machine 12

The rotating electric machine 12 may be a motor or a generator. For example, the rotating electric machine 12 may be the electric motor 106 or the electric motor 110 shown in FIG. 1. Alternatively, the rotating electric machine 12 may be a generator (not shown) provided in the moving object 100. The rotating electric machine 12 may be of an outer rotor type or an inner rotor type.

The rotating electric machine 12 includes a rotor 18, a stator 20, and a cooling flow path 22. The stator 20 includes a plurality of teeth. A coil is disposed in a slot between two adjacent teeth. The coil is cooled by a coolant flowing through the cooling flow path 22. For example, the cooling flow path 22 comprises a plurality of tubular channels arranged along the coil in each slot. Alternatively, the cooling flow path 22 comprises an annular channel that houses coils arranged around the stator 20. A first port 24 is located at one end of the cooling flow path 22 and a second port 26 is located at the other end of the cooling flow path 22. Each of the first port 24 and the second port 26 is disposed in the housing of the rotating electric machine 12.

In the cooling flow path 22, the coolant absorbs heat from the coil and the like. This increases the temperature of the coolant.

### Cooling Circuit 14

The cooling circuit 14 includes the cooling flow path 22 of the rotating electric machine 12. The cooling circuit 14 dissipates heat from the coolant discharged from the cooling flow path 22, and then supplies the coolant to the cooling flow path 22 again. In this way, the cooling circuit 14 circulates the coolant.

The cooling circuit 14 includes a pump 28. The pump 28 is an electric pump connected to an electric motor 30. The electric motor 30 is operated by electric power supplied from a motor driver 32. The pump 28 includes a suction port 36 and a discharge port 34. The pump 28 draws in the coolant from the suction port 36 and discharges the drawn-in coolant from the discharge port 34.

The cooling circuit 14 includes a heat sink 38. The heat sink 38 is attached to an inverter 40. The inverter 40 converts direct-current (DC) power supplied from a power supply source (a power generation device, a battery, or the like) into alternating-current (AC) power and supplies the AC power to the rotating electric machine 12. The heat sink 38 includes a heat sink flow path 42. The heat sink 38 includes an input port 44 located at one end of the heat sink flow path 42 and an output port 46 located at the other end of the heat sink flow path 42.

In the heat sink flow path 42, the coolant absorbs heat from the inverter 40. Accordingly, the temperature of the coolant increases.

The cooling circuit 14 includes a supply-side valve 48. The supply-side valve 48 is, for example, a two-position, three-port solenoid valve. The supply-side valve 48 includes an input port 50, a first output port 52, and a second output port 54. The valve body of the supply-side valve 48 operates in accordance with an electric signal supplied from the control device 16. When the valve body of the supply-side valve 48 is positioned at a first position, the input port 50 and the first output port 52 communicate with each other. When the valve body of the supply-side valve 48 is positioned at a second position, the input port 50 and the second output port 54 communicate with each other. The supply-side valve 48 may be a valve of another form.

The cooling circuit 14 includes a suction-side valve 56. The suction-side valve 56 is, for example, a two-position, three-port solenoid valve. The suction-side valve 56 includes a first input port 58, a second input port 60, and an output port 62. The valve body of the suction-side valve 56 operates in accordance with an electric signal supplied from the control device 16. When the valve body of the suction-side valve 56 is located at a first position, the first input port 58 and the output port 62 communicate with each other. When the valve body of the suction-side valve 56 is located at a second position, the second input port 60 and the output port 62 communicate with each other. The suction-side valve 56 may be a valve of another form.

The cooling circuit 14 includes a radiator 64. The radiator 64 includes a radiator flow path 65 through which the coolant flows and a ventilation path through which outside air passes. The radiator 64 includes an input port 66 located at one end of the radiator flow path 65 and an output port 68 located at the other end of the radiator flow path 65.

In the radiator flow path 65, the coolant releases heat to the outside air. Accordingly, the temperature of the coolant decreases.

The cooling circuit 14 includes a first flow path 70, a second flow path 72, a third flow path 74, a fourth flow path 76, a fifth flow path 78, a sixth flow path 80, a first branch flow path 82, and a second branch flow path 84.

The discharge port 34 of the pump 28 is connected to the input port 44 of the heat sink 38 via the first flow path 70. The output port 46 of the heat sink 38 is connected to the input port 50 of the supply-side valve 48 via the second flow path 72. The first output port 52 of the supply-side valve 48 is connected to the first input port 58 of the suction-side valve 56 via the third flow path 74. The second output port 54 of the supply-side valve 48 is connected to the second input port 60 of the suction-side valve 56 via the fourth flow path 76. The output port 62 of the suction-side valve 56 is connected to the input port 66 of the radiator 64 through the fifth flow path 78. The output port 68 of the radiator 64 is connected to the suction port 36 of the pump 28 via the sixth flow path 80.

The first branch flow path 82 branches from the third flow path 74 and is connected to the first port 24 of the rotating electric machine 12. The second branch flow path 84 branches from the fourth flow path 76 and is connected to the second port 26 of the rotating electric machine 12.

### Control Device 16

The control device 16 is configured by, for example, an electronic control unit (ECU). The control device 16 includes a computation unit 86 and a storage unit 88. The computation unit 86 is, for example, a processor such as a central processing unit (CPU), a graphics processing unit (GPU), or the like. The computation unit 86 includes a determination unit 90 and a control unit 92. The determination unit 90 and the control unit 92 are realized by the computation unit 86 executing a program stored in the storage unit 88. At least a part of the determination unit 90 and the control unit 92 may be realized by an integrated circuit such as an application specific integrated circuit (ASIC) or a field-programmable gate array (FPGA). At least a part of the determination unit 90 and the control unit 92 may be realized by an electronic circuit including a discrete device.

The storage unit 88 is a computer-readable non-transitory tangible storage medium. The storage unit 88 includes a volatile memory (not illustrated) and a non-volatile memory (not illustrated). The volatile memory is, for example, a random access memory (RAM). The non-volatile memory is, for example, a read only memory (ROM), a flash memory, or the like. Data and the like are stored in, for example, the volatile memory. Programs, tables, maps, and the like are stored, for example, in the non-volatile memory. At least a part of the storage unit 88 may be included in the processor, the integrated circuit, or the like as described above.

The determination unit 90 determines whether the coolant is to be supplied to the cooling flow path 22 from the first port 24 located at one end of the cooling flow path 22 or from the second port 26 located at the other end of the cooling flow path 22.

The control unit 92 controls supply of the coolant to the rotating electric machine 12. The control unit 92 controls the operation of the pump 28 via the motor driver 32. The control unit 92 controls the operation of the supply-side valve 48 and the suction-side valve 56 to control the direction of the flow of the coolant in the cooling flow path 22.

When the determination unit 90 determines that the coolant is to be supplied from the first port 24 to the cooling flow path 22, the control unit 92 performs first supply control for supplying the coolant from the first port 24 to the cooling flow path 22. When the determination unit 90 determines that the coolant is to be supplied from the second port 26 to the cooling flow path 22, the control unit 92 performs second supply control for supplying the coolant from the second port 26 to the cooling flow path 22. In the first embodiment, the control unit 92 selectively performs the first supply control and the second supply control by individually controlling the supply-side valve 48 and the suction-side valve 56.

### 2-2. First Supply Control and Second Supply Control

When the control unit 92 performs the first supply control, the input port 50 and the first output port 52 of the supply-side valve 48 are connected to each other as shown in FIG. 2. The second input port 60 and the output port 62 of the suction-side valve 56 are connected to each other. In this state, a flow path of the coolant from the discharge port 34 of the pump 28 to the third flow path 74 is formed. Further, a flow path of the coolant from the fourth flow path 76 to the suction port 36 of the pump 28 is formed. On the other hand, the flow path of the coolant from the discharge port 34 of the pump 28 to the fourth flow path 76 is blocked. Further, the flow path of the coolant from the third flow path 74 to the suction port 36 of the pump 28 is blocked. As a result, the first branch flow path 82 and the first port 24 of the cooling flow path 22 provided in the rotating electric machine 12 are connected to the discharge port 34 of the pump 28. The second branch flow path 84 and the second port 26 of the cooling flow path 22 provided in the rotating electric machine 12 are connected to the suction port 36 of the pump 28. Therefore, when the control unit 92 performs the first supply control, the coolant is supplied from the first port 24 to the inside of the cooling flow path 22 and is discharged from the second port 26 to the outside of the cooling flow path 22.

When the control unit 92 performs the second supply control, the input port 50 of the supply-side valve 48 and the second output port 54 are connected to each other as shown in FIG. 3. In the suction-side valve 56, the first input port 58 is connected to the output port 62. In this state, a flow path of the coolant from the discharge port 34 of the pump 28 to the fourth flow path 76 is formed. Further, a flow path of the coolant from the third flow path 74 to the suction port 36 of the pump 28 is formed. On the other hand, the flow path of the coolant from the discharge port 34 of the pump 28 to the third flow path 74 is blocked. Further, the flow path of the coolant from the fourth flow path 76 to the suction port 36 of the pump 28 is blocked. As a result, the second branch flow path 84 and the second port 26 of the cooling flow path 22 provided in the rotating electric machine 12 are connected to the discharge port 34 of the pump 28. The first branch flow path 82 and the first port 24 of the cooling flow path 22 provided in the rotating electric machine 12 are connected to the suction port 36 of the pump 28. Therefore, when the control unit 92 performs the second supply control, the coolant is supplied from the second port 26 to the inside of the cooling flow path 22 and is discharged from the first port 24 to the outside of the cooling flow path 22.

### 2-3. Cooling Process

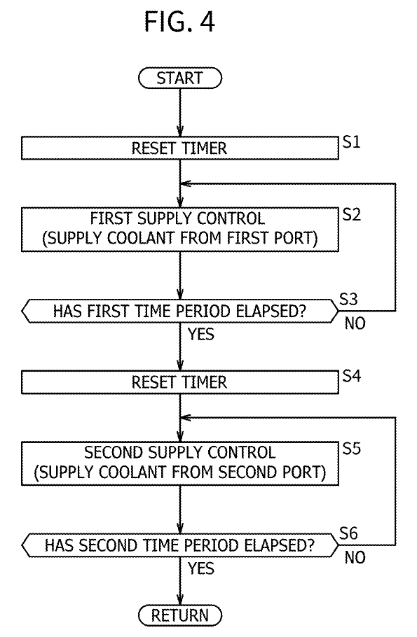

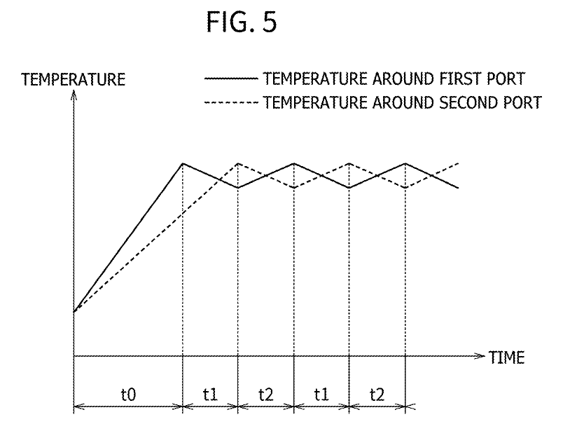

FIG. 4 is a flowchart of a cooling process according to the first embodiment. FIG. 5 is a graph showing a relationship between time and the temperature inside the rotating electric machine 12. FIG. 5 shows the temperature of each of the first coil end and the second coil end. The first port 24 is disposed around the first coil end. The second port 26 is disposed around the second coil end. That is, FIG. 5 shows the temperature around the first port 24 and the temperature around the second port 26.

When supply of electric power to the rotating electric machine 12 is started, the temperature of the rotating electric machine 12 gradually rises. When the supply of electric power to the rotating electric machine 12 is started, the control unit 92 instructs the motor driver 32 to start the operation of the pump 28. When the motor driver 32 supplies electric power to the electric motor 30, the pump 28 starts operating, and the supply of the coolant to the rotating electric machine 12 is started.

The control unit 92 alternately performs two controls, namely, the first supply control and the second supply control, and supplies the coolant to the rotating electric machine 12. In the first embodiment, the control unit 92 starts supplying the coolant to the rotating electric machine 12 by the second supply control of the two controls. As shown in FIG. 3, the coolant is supplied from the second port 26 to the inside of the cooling flow path 22 and is discharged from the first port 24 to the outside of the cooling flow path 22.

The coolant circulating through the cooling circuit 14 absorbs heat from the inverter 40 and the rotating electric machine 12 and dissipates heat in the radiator 64. After the circulation of the coolant is started, the temperature of the coolant gradually rises. In this state, the temperature of the coolant at the first port 24 is higher than the temperature of the coolant at the second port 26.

The determination unit 90 measures an elapsed time, by a timer (a software timer, a hardware timer, or the like), from a time point (start time point) at which the supply of the coolant to the rotating electric machine 12 is started, for example. When a predetermined time period (t0) has elapsed from the start of circulation of the coolant, the coolant process shown in FIG. 4 is started. The predetermined time period (t0) is stored in the storage unit 88 in advance.

In step S1, the determination unit 90 resets the timer. After the timer is reset, the process proceeds to step S2.

In step S2, the control unit 92 performs the first supply control. When the control unit 92 starts the first supply control, the measurement of time by the timer is restarted. The first supply control brings the cooling circuit 14 into a state shown in FIG. 2. Accordingly, the coolant is supplied from the first port 24 to the inside of the cooling flow path 22 and discharged from the second port 26 to the outside of the cooling flow path 22. When the first supply control is executed, the temperature around the first port 24 gradually decreases as shown in FIG. 5. On the other hand, the temperature around the second port 26 gradually increases.

In step S3, the determination unit 90 determines whether or not the first time period (t1) has elapsed from the time point (first start time point) at which the first supply control is started, based on the time measured by the timer. The first time period (t1) can be set as desired. The first time period (t1) is stored in the storage unit 88 in advance. When the first time period (t1) has elapsed from the first start time point (step S3: YES), the process proceeds to step S4. On the other hand, when the first time period (t1) has not elapsed from the first start time point (step S3: NO), step S2 is continued.

When the process proceeds from step S3 to step S4, the determination unit 90 resets the timer. After the timer is reset, the process proceeds to step S5.

In step S5, the control unit 92 performs the second supply control. When the control unit 92 starts the second supply control, the measurement of time by the timer is restarted. The second supply control brings the cooling circuit 14 into a state shown in FIG. 3. Accordingly, the coolant is supplied from the second port 26 to the inside of the cooling flow path 22 and is discharged from the first port 24 to the outside of the cooling flow path 22. When the second supply control is executed, the temperature around the second port 26 gradually decreases as shown in FIG. 5. On the other hand, the temperature around the first port 24 gradually rises.

In step S6, the determination unit 90 determines whether or not the second time period (t2) has elapsed from the time point (second start time point) at which the second supply control is started, based on the time measured by the timer. The second time period (t2) can be set as desired. The second time period (t2) may be the same as or different from the first time period (t1). The second time period (t2) is stored in the storage unit 88 in advance. When the second time period (t2) has elapsed from the second start time point (step S6: YES), the process returns to step S1. On the other hand, when the second time period (t2) has not elapsed from the second start time point (step S6: NO), step S5 is continued.

As described above, according to the first embodiment, the first supply control and the second supply control are performed alternately. This makes it possible to reduce a difference in cooling temperature inside the rotating electric machine 12 while suppressing an increase in the size of the system.

### 3. Cooling System 10 according to Second Embodiment

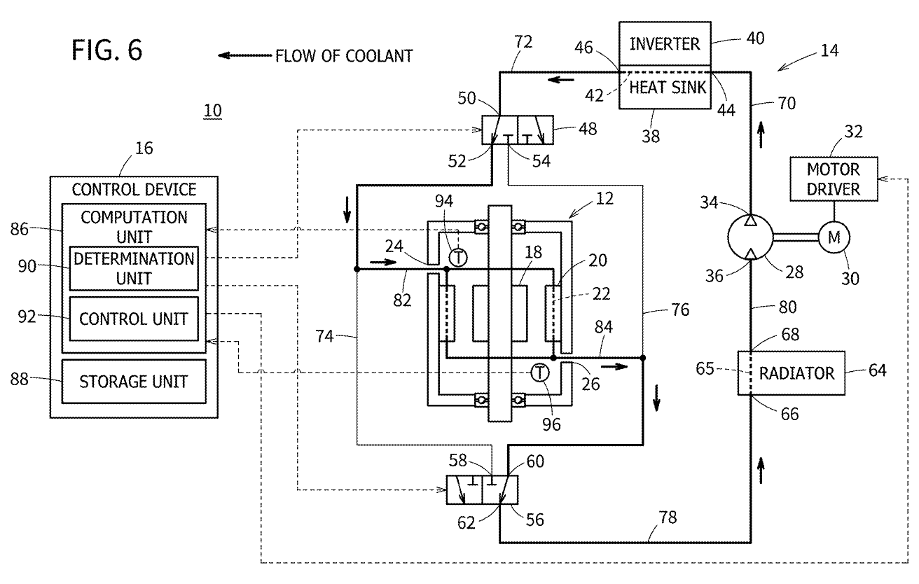

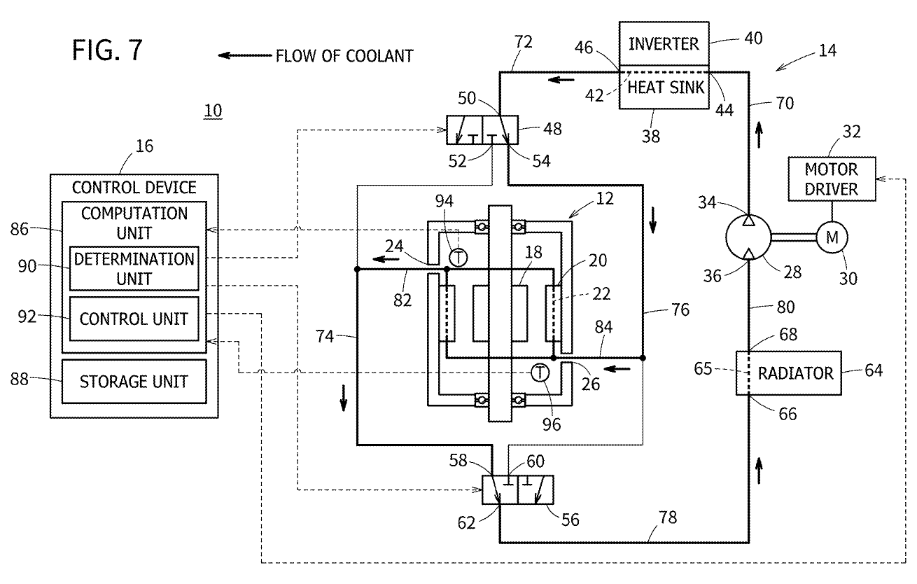

FIGS. 6 and 7 are schematic views of a cooling system 10 according to a second embodiment. FIG. 6 shows the cooling system 10 in a state where the first supply control is being performed. FIG. 7 shows the cooling system 10 in a state where the second supply control is being performed. In the second embodiment, parts different from the first embodiment will be described, and the description of the same parts as the first embodiment will be omitted.

A first temperature sensor 94 and a second temperature sensor 96 are disposed in the cooling circuit 14. The first temperature sensor 94 detects the temperature of the coolant at the first port 24. The second temperature sensor 96 detects the temperature of the coolant at the second port 26. Each of the first temperature sensor 94 and the second temperature sensor 96 may be disposed inside the rotating electric machine 12 or may be disposed outside the rotating electric machine 12.

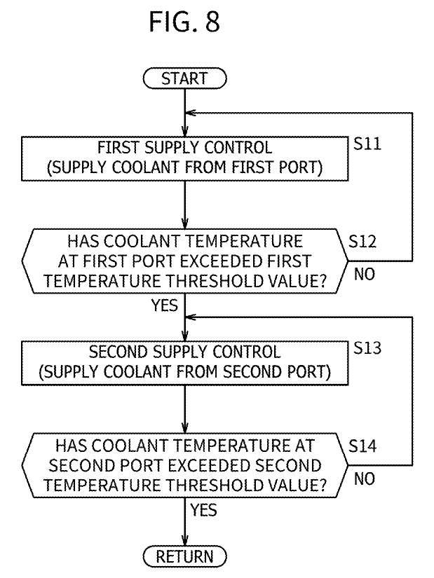

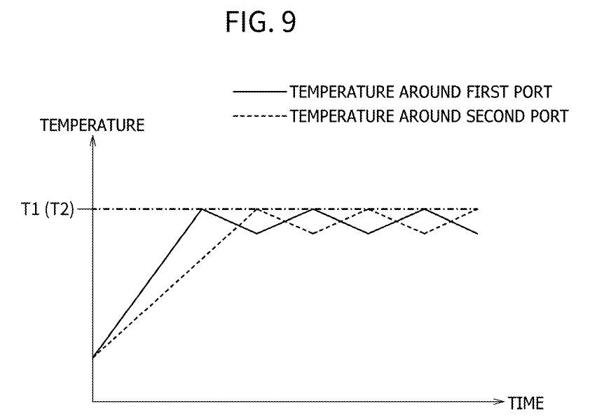

FIG. 8 is a flowchart of a cooling process according to the second embodiment. FIG. 9 is a graph showing a relationship between time and the temperature inside the rotating electric machine 12. Similarly to FIG. 5, FIG. 9 shows the temperature of each of the first coil end and the second coil end. That is, FIG. 9 shows the temperature around the first port 24 and the temperature around the second port 26.

In step S11, the control unit 92 performs the first supply control. The first supply control brings the cooling circuit 14 into a state shown in FIG. 6. Accordingly, the coolant is supplied from the first port 24 to the inside of the cooling flow path 22 and discharged from the second port 26 to the outside of the cooling flow path 22. When the first supply control is executed, the temperature around the first port 24 gradually decreases as shown in FIG. 9. On the other hand, the temperature around the second port 26 gradually increases.

In step S12, the determination unit 90 determines whether the temperature of the coolant at the first port 24 exceeds a first temperature threshold value (T1) or not, based on the temperature detected by the first temperature sensor 94. In the present embodiment, the amount of heat generated by the coil is estimated based on the temperature detected by the temperature sensor, however the present invention is not limited to this. For example, the determination unit 90 may estimate the temperature of the coil based on the flow rate of the coolant and electric current flowing through the coil, and determine whether the estimated temperature exceeds the first temperature threshold value. The first temperature threshold value (T1) can be set as desired. The first temperature threshold value (T1) is stored in the storage unit 88 in advance. When the temperature of the coolant at the first port 24 exceeds the first temperature threshold value T1 (step S12: YES), the process proceeds to step S13. On the other hand, when the temperature of the coolant at the first port 24 does not exceed the first temperature threshold value T1 (step S12: NO), step S11 is continued.

When the process proceeds from step S12 to step S13, the control unit 92 performs the second supply control. The second supply control brings the cooling circuit 14 into a state shown in FIG. 7. Accordingly, the coolant is supplied from the second port 26 to the inside of the cooling flow path 22 and is discharged from the first port 24 to the outside of the cooling flow path 22. When the second supply control is executed, the temperature around the second port 26 gradually decreases as shown in FIG. 9. On the other hand, the temperature around the first port 24 gradually rises.

In step S14, the determination unit 90 determines whether the temperature of the coolant at the second port 26 exceeds the second temperature threshold value (T2) or not, based on the temperature detected by the second temperature sensor 96. The second temperature threshold value (T2) can be set as desired. The second temperature threshold value (T2) may be the same as or different from the first temperature threshold value (T1). The second temperature threshold value (T2) are stored in the storage unit 88 in advance. When the temperature of the coolant at the second port 26 exceeds the second temperature threshold value T2 (step S14: YES), the process returns to step S11. On the other hand, when the temperature of the coolant at the second port 26 does not exceed the second temperature threshold value T2 (step S14: NO), step S13 is continued.

As described above, according to the second embodiment, the first supply control and the second supply control are alternately performed. This makes it possible to reduce a difference in cooling temperature inside the rotating electric machine 12 while suppressing an increase in the size of the system.

### 4. Cooling System 10 according to Third Embodiment

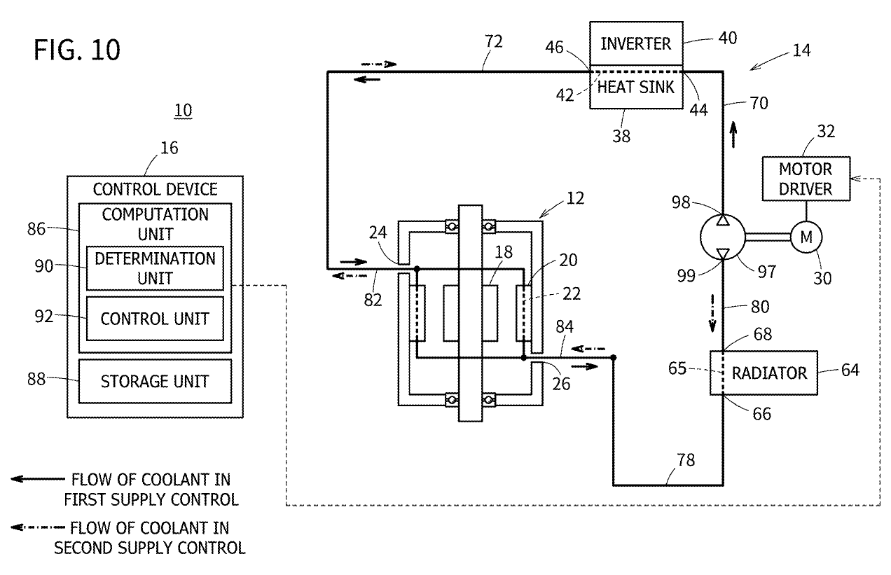

FIG. 10 is a schematic view of a cooling system 10 according to a third embodiment. In the third embodiment, portions different from the first embodiment and the second embodiment will be described, and description of the same portions as the first embodiment will be omitted.

In the third embodiment, the pump 97 is a bidirectional pump. The pump 97 draws in the coolant from the second port 99 and discharges the drawn-in coolant from the first port 98, by rotating in the first direction. The pump 97 rotates in a second direction opposite to the first direction to draw in the coolant from the first port 98 and discharge the drawn-in coolant from the second port 99.

The first port 98 of the pump 97 is connected to the first port 24 of the rotating electric machine 12 via the first flow path 70, the heat sink 38, and the second flow path 72. On the other hand, the second port 99 of the pump 97 is connected to the second port 26 of the rotating electric machine 12 via the sixth flow path 80, the radiator 64, and the fifth flow path 78.

In the first supply control, the control unit 92 rotates the pump 97 in the first direction. In the second supply control, the control unit 92 rotates the pump 97 in the second direction. In the third embodiment, the cooling process is performed in the same procedure as the flowchart shown in FIG. 4.

In the third embodiment, the first temperature sensor 94 and the second temperature sensor 96 may be used as in the second embodiment. In this case, the cooling process is performed in the same procedure as the flowchart shown in FIG. 8.

### 5. Supplementary Notes

The following Supplementary Notes are further disclosed in relation to the above embodiments.

### SUPPLEMENTARY NOTE 1

The control device (16) of the present disclosure is a control device provided in the cooling system (10) that supplies coolant to the cooling flow path (22) provided in the rotating electric machine (12), and includes the determination unit (90) that determines whether coolant is to be supplied to the cooling flow path from the first port (24) located at one end of the cooling flow path or from the second port (26) located at the other end of the cooling flow path, and the control unit (92) that performs the first supply control for supplying coolant from the first port to the cooling flow path when the determination unit determines that coolant is to be supplied from the first port to the cooling flow path, and performs the second supply control for supplying coolant from the second port to the cooling flow path when the determination unit determines that coolant is to be supplied from the second port to the cooling flow path.

According to the above configuration, the first supply control and the second supply control are alternately performed. Accordingly, it is possible to reduce a difference in cooling temperature inside the rotating electric machine while suppressing an increase in the size of the system.

### SUPPLEMENTARY NOTE 2

In the control device according to Supplementary Note 1, the determination unit may determine that coolant is to be supplied from the second port to the cooling flow path, based on the first time period having elapsed from start of supplying coolant from the first port to the cooling flow path, and determine that coolant is to be supplied from the first port to the cooling flow path, based on the second time period having elapsed from start of supplying coolant from the second port to the cooling flow path.

### SUPPLEMENTARY NOTE 3

In the control device according to Supplementary Note 1, the determination unit may determine that coolant is to be supplied from the second port to the cooling flow path, based on the temperature of coolant discharged from the second port exceeding the first temperature threshold value, and determine that coolant is to be supplied from the first port to the cooling flow path, based on the temperature of coolant discharged from the first port exceeding the second temperature threshold value.

### SUPPLEMENTARY NOTE 4

In the control device according to Supplementary Note 1, the cooling system may include the pump (28) that discharges coolant, and the supply-side valve (48) that allows one of the first port or the second port of the cooling flow path to communicate with the discharge port (34) of the pump, and the control unit may, in the first supply control, control the supply-side valve to allow the first port of the cooling flow path to communicate with the discharge port of the pump, and in the second supply control, control the supply-side valve to allow the second port of the cooling flow path to communicate with the discharge port of the pump.

### SUPPLEMENTARY NOTE 5

In the control device according to Supplementary Note 4, the cooling system may include the suction-side valve (56) configured to selectively allow one of the first port or the second port of the cooling flow path to communicate with the suction port (36) of the pump, and the control unit may, in the first supply control, control the suction-side valve to allow the second port of the cooling flow path to communicate with the suction port of the pump, and in the second supply control, control the suction-side valve to allow the first port of the cooling flow path to communicate with the suction port of the pump.

### SUPPLEMENTARY NOTE 6

In the control device according to Supplementary Note 1, the cooling system may include the pump (97) configured to discharge coolant to the first port of the cooling flow path by rotating in the first direction and to discharge coolant to the second port of the cooling flow path by rotating in the second direction opposite to the first direction, and the control unit may rotate the pump in the first direction in the first supply control, and rotate the pump in the second direction in the second supply control.

### SUPPLEMENTARY NOTE 7

The cooling system of the present disclosure is a cooling system including the control device according to Supplementary Note 1, wherein a flow path (42) for cooling the inverter (40) with coolant is disposed between the discharge port of the pump that discharges coolant and the cooling flow path of the rotating electric machine, the inverter being configured to supply AC power to the rotating electric machine.

### SUPPLEMENTARY NOTE 8

The moving object (100) of the present disclosure includes the cooling system including the control device according to any one of Supplementary Notes 1 to 6.

### SUPPLEMENTARY NOTE 9

The control method of the present disclosure is a control method for the cooling system that supplies coolant to the cooling flow path provided in the rotating electric machine, and includes the determination step of determining whether coolant is to be supplied to the cooling flow path from the first port located at one end of the cooling flow path or from the second port located at the other end of the cooling flow path; and the control step of performing the first supply control for supplying coolant from the first port to the cooling flow path when the determination step determines that coolant is to be supplied from the first port to the cooling flow path, and performing the second supply control for supplying coolant from the second port to the cooling flow path when the determination step determines that coolant is to be supplied from the second port to the cooling flow path.

### SUPPLEMENTARY NOTE 10

A program according to the present disclosure causes a computer to execute the control method according to Supplementary Note 9.

Although the present disclosure has been described in detail, the present disclosure is not limited to the above-described embodiments. In these embodiments, various addition, replacement, changing, partial deletions, and the like can be made without departing from the essence and gist of the present disclosure or without departing from the essence and gist of the present disclosure derived from the contents described in the claims and equivalents thereof. These embodiments may also be implemented in combination. For example, in the above-described embodiments, the order of operations and the order of processes are shown as examples, and the present invention is not limited to them. The same applies to a case where numerical values or mathematical equations are used in the description of the above-described embodiments.

1. A control device provided in a cooling system configured to supply coolant to a cooling flow path provided in a rotating electric machine, the control device comprising:
one or more processors that execute computer-executable instructions stored in a memory,
wherein the one or more processors execute the computer-executable instructions to cause the control device to:
determine whether coolant is to be supplied to the cooling flow path from a first port located at one end of the cooling flow path or from a second port located at another end of the cooling flow path; and
perform first supply control for supplying coolant from the first port to the cooling flow path when it is determined that coolant is to be supplied from the first port to the cooling flow path, and perform second supply control for supplying coolant from the second port to the cooling flow path when it is determined that coolant is to be supplied from the second port to the cooling flow path.

2. The control device according to claim 1, wherein
the one or more processors execute the computer-executable instructions to cause the control device to:
determine that coolant is to be supplied from the second port to the cooling flow path, based on a first time period having elapsed from start of supplying coolant from the first port to the cooling flow path, and determine that coolant is to be supplied from the first port to the cooling flow path, based on a second time period having elapsed from start of supplying coolant from the second port to the cooling flow path.

3. The control device according to claim 1, wherein
the one or more processors execute the computer-executable instructions to cause the control device to:
determine that coolant is to be supplied from the second port to the cooling flow path, based on a temperature of coolant discharged from the second port exceeding a first temperature threshold value, and determine that coolant is to be supplied from the first port to the cooling flow path, based on the temperature of coolant discharged from the first port exceeding a second temperature threshold value.

4. The control device according to claim 1, wherein
the cooling system includes a pump configured to discharge coolant, and a supply-side valve configured to selectively allow one of the first port or the second port of the cooling flow path to communicate with a discharge port of the pump, and
the one or more processors execute the computer-executable instructions to cause the control device to:
in the first supply control, control the supply-side valve to allow the first port of the cooling flow path to communicate with the discharge port of the pump, and in the second supply control, control the supply-side valve to allow the second port of the cooling flow path to communicate with the discharge port of the pump.

5. The control device according to claim 4, wherein
the cooling system includes a suction-side valve configured to selectively allow one of the first port or the second port of the cooling flow path to communicate with a suction port of the pump, and
the one or more processors execute the computer-executable instructions to cause the control device to:
in the first supply control, control the suction-side valve to allow the second port of the cooling flow path to communicate with the suction port of the pump, and in the second supply control, control the suction-side valve to allow the first port of the cooling flow path to communicate with the suction port of the pump.

6. The control device according to claim 1, wherein
the cooling system includes a pump configured to discharge coolant to the first port of the cooling flow path by rotating in a first direction and to discharge coolant to the second port of the cooling flow path by rotating in a second direction opposite to the first direction, and
the one or more processors execute the computer-executable instructions to cause the control device to:
rotate the pump in the first direction in the first supply control, and rotate the pump in the second direction in the second supply control.

7. A cooling system comprising the control device according to claim 1, wherein
a flow path for cooling an inverter with coolant is disposed between a discharge port of a pump configured to discharge coolant and the cooling flow path of the rotating electric machine, the inverter being configured to supply alternating-current power to the rotating electric machine.

8. A moving object comprising a cooling system including the control device according to claim 1.

9. A control method for causing one or more processors to control a cooling system configured to supply coolant to a cooling flow path provided in a rotating electric machine, the control method comprising:
determining whether coolant is to be supplied to the cooling flow path from a first port located at one end of the cooling flow path or from a second port located at another end of the cooling flow path; and
performing first supply control for supplying coolant from the first port to the cooling flow path when, in the determining, it is determined that coolant is to be supplied from the first port to the cooling flow path, and performing second supply control for supplying coolant from the second port to the cooling flow path when, in the determining, it is determined that coolant is to be supplied from the second port to the cooling flow path.

10. A non-transitory storage medium storing a program for causing a computer to execute the control method according to claim 9.
